(19) United States
(12) Patent Application Publication
(10) Pub. No.: US 2006/0022691 A1
(43) Pub. Date: Feb. 2, 2006

(54) Semiconductor device

(75) Inventors: Takanori Watanabe, Bunkyo (JP); Masashi Takase, Kawasaki (JP); Noboru Kosugi, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/242,082

(22) Filed: Oct. 4, 2005

Related U.S. Application Data
(63) Continuation of application No. PCT/JP03/04617, filed on Apr. 11, 2003.

(51) Int. Cl. G01R 31/02

(52) U.S. Cl. 324/754

(57) ABSTRACT

It is able to restrict increase of a chip area even if the pad pitch is reduced and the pad length is increased in a semiconductor device by arranging pads (4, 5), comprising electrically connected first and second regions having different number of wiring layers, above an I/O circuit (2).

### TECHNICAL FIELD

The present invention relates to a semiconductor device, and particularly to an arrangement and structure of a pad in a semiconductor device.

### BACKGROUND ART

A conventional configuration of a semiconductor device will be described in accordance with FIG. 6.

FIG. 6 is a view schematically showing an example of a configuration of the conventional semiconductor device. In FIG. 6, a part of the peripheral portion of a semiconductor chip 11 in which the semiconductor device is formed is shown.

In FIG. 6, a reference numeral 12 refers to an input/output (I/O) circuit for inputting and outputting electrical signals to an internal circuitry (not shown) formed in the center portion of the semiconductor chip 11, and a reference numeral 13 refers to a pad for electrically connecting the semiconductor device with external equipments or the like, for example, through wire bonding.

As shown in FIG. 6, in the conventional semiconductor device, the I/O circuit 12 is formed in array on the outer portion of the semiconductor chip 11, and the pad 13 is formed between the I/O circuit 12 and an edge 14 of the semiconductor chip 11. This is for preventing the occurrence of inconveniences such that moisture penetrates the I/O circuit 12 or the like through a crack or the like when a crack or the like occurs in the pad 13 due to probing inspection which will be described later. In addition, the I/O circuit 12 and the pad 13 are electrically connected by a via portion which connects wirings in a lower layer and wirings between different layers.

Moreover, semiconductor device, after finishing the process, is carried out a probing inspection for inspecting its electrical characteristics formed. The probing inspection is carried out inputting and outputting electrical signals by causing a probe needle to contact to the pad 13. As for the probing inspection, there are a method utilizing a cantilever and a method utilizing photo lithography.

One example of the conventional semiconductor device and the probing inspection method thereof is disclosed in Japanese Patent Application Laid Open No. Hei 8-29451 (Patent Document 1).

If photo lithography is utilized for the probing inspection, the area of the region to which the probe needle is caused to contact in the pad can be reduced, however the manufacturing cost and the running cost are very high.

On the other hand, if a cantilever is utilized for the probing inspection, the manufacturing cost and the running cost is very inexpensive compared with the case where the photo lithography is utilized. However, in the case where the cantilever is utilized, if the pad pitch (a pad interval) is reduced due to the progress of the process technologies or the like, the area of the region to which the probe needle is in contact in the pad will increase.

FIGS. 7A to 7D are views for illustrating the increase of the area of the region to which the probe needle is in contact, involved in the reduction of the pad pitch. In FIGS. 7A to 7D, the reference numeral 13 refers to the pad, and the reference numeral 16 refers to a probe board comprising a cantilever probe needle 15.

As shown in FIG. 7A, in the case where the pad pitch (the interval of the pad 13) is wide, the interval of the probe needle 15 is secured sufficiently, and the length LP of the region to which the probe needle 15 in contact in the pad 13 is short as shown in FIG. 7B. FIG. 7B is the view seen from the arrow C of FIG. 7A.

On the contrary, as shown in FIG. 7C, in the case where the pad pitch is narrow, the amount to be taken into the probe board 16 needs to be increased in order to secure the interval of the probe needle 15 because the size of the probe needle 15 is predetermined. Thereby, as shown in FIG. 7D which is the view seen from the arrow D of FIG. 7C, the length LP of the region to which the probe needle 15 contacts in the pad 13 becomes long.

As the length LP of the region to which the probe needle 15 is caused to contact in the pad 13 becomes long, as described above, the length of the pad 13 will increase and thus the useless chip area in the semiconductor device will increase. As a result, the manufacturing cost and the running cost of the semiconductor device will increase. Moreover, irregularities will be produced on the surface of the pad 13 due to the contacting of the probe needle 15, thereby, the wire-bonding strength will decrease owing to these irregularities. Accordingly, as the region to which the probe needle 15 is in contact in the pad 13 becomes wide, the region usable for the wire bonding in the pad 13 becomes narrow, and thus it is very difficult to find out the position to be wire-bonded.
[Patent document 1] Japanese Patent Application laid-open No. Hei 8-29451

### SUMMARY OF THE INVENTION

The present invention has been made in view of such a situation, and is intended to able to restrict increase of a chip area even if the pad pitch is reduced in a semiconductor device.

In the semiconductor device according to the present invention, a pad, comprising electrically connected first and second regions having mutually different numbers of wiring layers is arranged above an I/O circuit. According to the present invention, even if the pad pitch is reduced in the semiconductor device and thus the pad length is increases, it is able to restrict the increase of the chip area, because the pad is arranged above the I/O circuit unlike the conventional one. Accordingly, a probing inspection using a cantilever can be carried out and the manufacturing cost can be reduced as compared with the conventional one. Moreover, because at least one of the numbers of wiring layers of the first and second regions becomes plural, the occurrence of inconveniences due to the probing inspection or the like can be prevented by using one region having a plural number of wiring layer for the probing inspection or the like, and by using the other region for bonding, and at the same time the decrease of the wire-bonding strength can be prevented.

### BRIEF DESCRIPTION OF THE DRAWINGS

FIG. 1A and FIG. 1B are views showing an example of the configuration of the semiconductor device according to a first embodiment of the present invention.

FIG. 2 is a view showing another example of the configuration of the semiconductor device according to the first embodiment.

FIG. 3A and FIG. 3B are views showing opening regions in a cover layer.

FIG. 4A and FIG. 4B are views showing an example of the configuration of the semiconductor device according to a second embodiment of the present invention.

FIG. 5 is a view showing another example of the configuration of the semiconductor device according to the second embodiment.

FIG. 6 is a view showing a configuration of the conventional semiconductor device.

FIGS. 7A to 7D are views for illustrating problems in the conventional art.

### DETAILED DESCRIPTION OF THE PREFERRED EMBODIMENTS

Hereafter, embodiments of the present invention will be described in accordance with the accompanying drawings.

### A First Embodiment

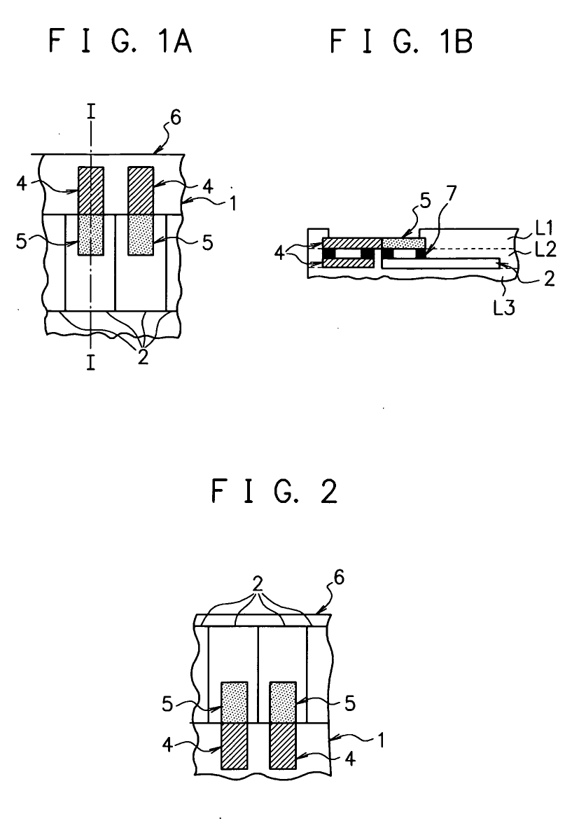

FIG. 1A and FIG. 1B are views showing an example of the configuration of the semiconductor device according to a first embodiment of the present invention, and show a part of the outer portion of the semiconductor chip 1 in which the semiconductor device is formed (the same for a second embodiment which will be described later).

FIG. 1A schematically shows the top surface of the semiconductor device according to the first embodiment. In FIG. 1A, a reference numeral 2 refers to an I/O circuit for inputting and outputting electrical signals to an internal circuitry (not shown) formed in the center portion of the semiconductor chip 1, a reference numeral 4 refers to a probing region to which a probe needle is caused to contact in the pad at the time of probing inspection, and a reference numeral 5 refers to a bonding region used for wire-bonding in order to electrically connect the semiconductor device with external equipments in the pad. That is, in the first embodiment, the pad comprises the electrically connected probing region 4 and bonding region 5. In addition, a reference numeral 6 refers to the edge of the semiconductor chip 1.

As shown in FIG. 1A, the I/O circuit 2 is arranged in array on the outer portion of the semiconductor chip 1, and, as for the pad comprising the probing region 4 and bonding region 5, the bonding region 5 is arranged above the I/O circuit 2 (so as to overlap when seen from the normal line direction of the substrate) in between the I/O circuit 2 and the edge 6 of the semiconductor chip 1.

FIG. 1B schematically shows the cross section along the line I-I in FIG. 1A.

As shown in FIG. 1B, the probing region 4 and the bonding region 5 differ in the number of pad stacking layers (the number of wiring layers). The probing region 4 comprising a first pad formed in a first wiring layer L1 that is the uppermost layer, and a second pad formed in a second wiring layer L2 that is one immediately below of L1, and these first and second pads are electrically connected through the via portion 7.

Moreover, the bonding region 5 comprises the first pad formed in the first wiring layer L1. The first pad of the bonding region 5 is formed above a part of the metal wiring layer that forms the I/O circuit 2 formed in the second wiring layer L2 of the lower layer, and is electrically connected with the metal wiring layer forming the I/O circuit 2, through the via portion 7.

Moreover, the first pad of the probing region 4 and the first pad of the bonding region 5 are electrically connected, and formed of one metal film, for example. In addition, the second pad of the probing region 4 formed on the second wiring layer L2 and the metal wiring layer which forms the I/O circuit 2 formed on the same wiring layer L2 are electrically isolated via an insulating film. Here, the first and the second pads of the probing region 4, and the first pad of the bonding region 5 are formed of an aluminum layer, for example, and the via portion 7 is formed of tungsten, for example.

As described up to now, the pad, comprising the electrically connected probing region 4 and bonding region 5 having mutually different numbers of the stacking pad layers, is arranged so that the bonding region 5 and the I/O circuit 2 may overlap when seen from the normal line of the substrate, and in the second wiring layer L2, which is the lower layer of the bonding region 5 and in which the second pad of the probing region 4 is formed, a part of the I/O circuit 2 is formed.

Thereby, because even if the pad pitch is reduced, the bonding region 5 is arranged so as to overlap above the I/O circuit 2, it is able to restrict increase of the chip area due to the reduction of the pad pitch. Moreover, by dividing the pad into the probing region 4 and the bonding region 5, and by forming the probing region 4 with a plurality of pads having different layers, the resistance to a mechanical stress can be improved and the occurrence of a crack can be suppressed, and at the same time even if a crack or the like occurs due to the probing inspection or the like, the influence thereof can be suppressed from extending to the I/O circuit 2 or the like. Moreover, with the bonding region 5 separately prepared, the decrease of the wire-bonding strength can be prevented and thus the bonding can be carried out with a sufficient strength. Accordingly, even if the pad pitch is reduced, it is possible to restrict the increase of the chip size, and to carry out the probing inspection using a cantilever, and to reduce the manufacturing cost or the like as compared with the conventional one.

In addition, although the pad comprising the probing region 4 and the bonding region 5 is arranged between the I/O circuit 2 and the edge 6 of the semiconductor chip 1 as described above, the pad comprising the probing region 4 and the bonding region 5 may be arranged central side of the I/O circuit 2 in the semiconductor, as shown in FIG. 2.

FIG. 2 is a view schematically showing, from the top face, another example of the configuration of the semiconductor device according to the first embodiment. The pad comprising the probing region 4 and the bonding region 5 is arranged so that the bonding region 5 is arranged in above-position of the I/O circuit 2. Moreover, the I/O circuit 2 is formed in the outer portion of the semiconductor chip 1 relative to the probing region 4. In this way, the chip area can be made further smaller.

In addition, in the above FIG. 1A, FIG. 1B, and FIG. 2, the pad comprising the probing region 4 and the bonding region 5 is arranged so that the bonding region 5 is positioned above the I/O circuit 2, however, not limited to this, a part of the bonding region 5 may be positioned above the I/O circuit 2.

Here, an opening region of a cover layer, which is prepared on top of the pad comprising the probing region 4 and the bonding region 5, will be described.

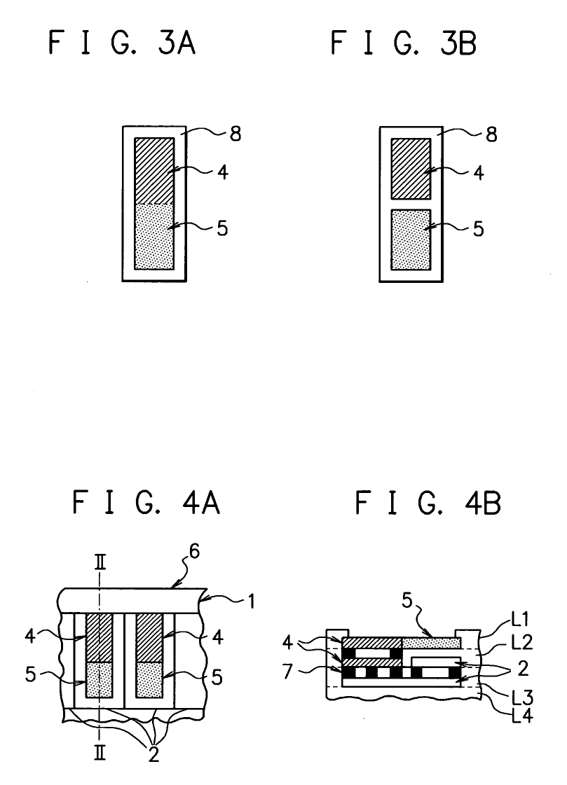

FIG. 3A and FIG. 3B are views showing one example of the opening region of the cover layer, and FIG. 3A shows an example of preparing a cover film 8 in the periphery of the pad comprising the probing region 4 and the bonding region 5.

Moreover, FIG. 3B shows an example of preparing the cover film 8 in the outside of the probing region 4 and the bonding region 5, respectively, wherein when seen from the top face, a portion in between the probing region 4 and the bonding region 5 is divided by the cover film 8. As shown in FIG. 3B, if two opening regions of the cover layer are prepared, influence from the probing inspection, such as an impact due to the contacting of the probe needle to the probing region 4, would not be exerted upon the bonding region 5 at all, and thus at the time of bonding, bonding with a sufficient strength can be carried out.

### A Second Embodiment

Next, a second embodiment of the present invention will be described. In the first embodiment described above, for the pad comprising the probing region 4 and the bonding region 5, only the bonding region 5 is arranged above the I/O circuit 2. In the second embodiment described hereinafter, the whole of the pad comprising the probing region 4 and the bonding region 5 is arranged above the I/O circuit 2.

FIG. 4A and FIG. 4B are views showing an example of the configuration of the semiconductor device according to the second embodiment of the present invention, and show a part of the outer portion of the semiconductor chip 1 in which the semiconductor device is formed. In addition, in FIG. 4A and FIG. 4B, the same numerals are given to the components having the same functions as those of the components shown in FIG. 1A and FIG. 1B, and the duplicated description will be omitted.

FIG. 4A shows schematically the top face of the semiconductor device according to the second embodiment. As shown in FIG. 4A, the I/O circuit 2 is arranged in the outer portion of the semiconductor chip 1, and the pad comprising the probing region 4 and the bonding region 5 is arranged at the edge 6 side above the I/O circuit 2 so that the whole of the pad and the I/O circuit 2 may overlap when seen from the normal line of the substrate.

FIG. 4B shows schematically the cross section along II-II in FIG. 4A.

As shown in FIG. 4B, the probing region 4 and the bonding region 5 of the pad differ in the number of the stacking pad layers, and the probing region 4 comprises a first pad formed in the first wiring layer L1 that is the uppermost layer, and a second pad formed in the second wiring layer L2 that is one immediately below of L1, and these first and second pads are electrically connected through the via portion 7.

Moreover, the bonding region 5 comprises the first pad formed in the first wiring layer L1. The first pad of the probing region 4 and the first pad of the bonding region 5 are electrically connected, and formed of one metal layer, for example. The first and second pads of the probing region 4, and the first pad of the bonding region 5 are formed of an aluminum layer, for example, and the via portion 7 is formed of tungsten, for example.

The I/O circuit 2 is formed, including a metal wiring layer formed in the second wiring layer L2, and a metal wiring layer formed in a third wiring layer L3, which is one layer below. The wiring layers formed in the second and third wiring layers L2 and L3 is electrically connected though the via portion 7.

Here, the first and second pads of the probing region 4, and the first pad of the bonding region 5 are formed above the metal wiring layer constituting the I/O circuit 2. Moreover, the second pad of the probing region 4 is electrically connected through the via portion 7 with the metal wiring layer formed in the third wiring layer L3 constituting the I/O circuit 2. In addition, the second pad of the probing region 4 formed in the second wiring layer L2, and the metal wiring layer constituting the I/O circuit 2 that is formed in the same wiring layer L2, are electrically isolated via an insulating film.

As described above, according to the second embodiment, in addition to the above-described effect obtained in the first embodiment, the chip area can be made further smaller by arranging the whole of the pad comprising the probing region 4 and the bonding region 5 above the I/O circuit 2.

Here, in the second embodiment, the total number of wiring layers in the pad portion increases by one layer including the circuit formed down below the pad as compared with the first embodiment, however, the first or second embodiment may be adequately used according to the number of layers of the circuit formed down below the pad.

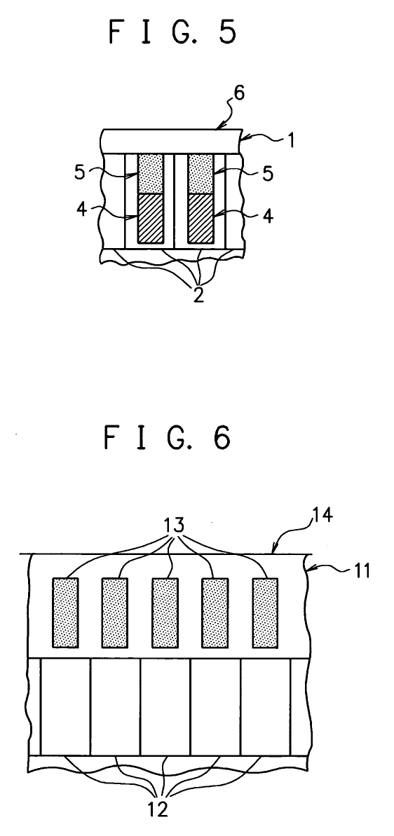

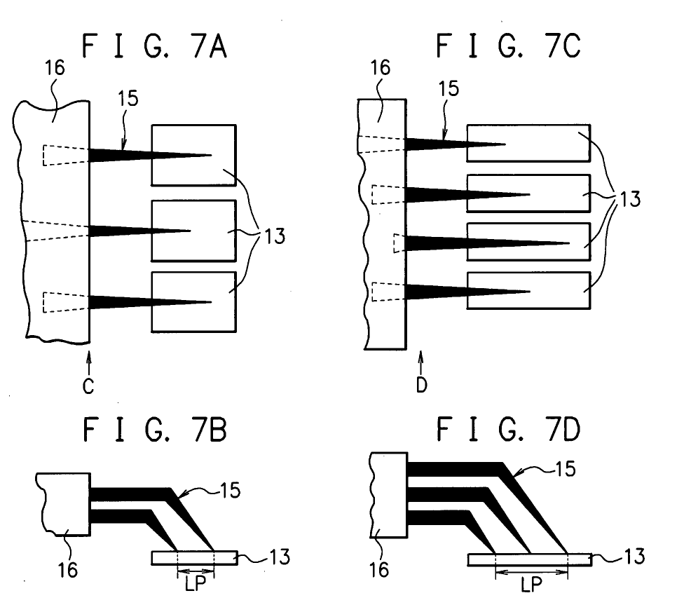

In addition, in the above description, for the pad comprising the probing region 4 and the bonding region 5, the whole of the pad is positioned above the I/O circuit 2, and at the same time the probing region 4 is arranged at the edge 6 side, however, as shown in FIG. 5, the bonding region 5 may be arranged at the edge 6 side.

In addition, although in the above first and second embodiments, the case where the number of wiring layers of the probing region 4 is one and the number of wiring layers of the bonding region 5 is two has been shown as one example, the present invention is not limited to this, and the number of wiring layers of the bonding region 5 just has to be fewer than the number of wiring layers of the probing region 4, and thus the number of wiring layers of the probing region 4 and the bonding region 5 is arbitrary, respectively. Moreover, the shape of the pad comprising the probing region 4 and the bonding region 5 is also one example, and may be changed, for example, according to the bonding method, suitably.

Moreover, each of the above-described embodiments show just one concept example for implementing the present invention, and with these embodiments, the technical scope of the present invention has not be interpreted limitedly. Namely, the present invention can be implemented in various forms without departing from the spirit and scope or the major characteristics of the invention.

### INDUSTRIAL APPLICABILITY

As described above, according to the present invention, by arranging a pad, comprising electrically connected first and second regions having mutually different number of wiring layers, above an I/O circuit, the increase of a chip area can be suppressed even if the pad pitch is reduced. Accordingly, even if the pad pitch is reduced, it is possible to restrict increase of the chip size, and to carry out the probing inspection using a cantilever, and to reduce the manufacturing cost as compared with the conventional one.

What is claimed is:

1. A semiconductor device provided with an I/O circuit, the semiconductor device comprising:
a pad having electrically connected first and second regions being mutually different number of wiring layers, wherein said pad is arranged above said I/O circuit.

2. The semiconductor device according to claim 1, wherein a part of said pad is arranged above said I/O circuit.

3. The semiconductor device according to claim 2, wherein said pad is arranged at the edge side of said semiconductor chip, in which said semiconductor device is formed, relative to said I/O circuit.

4. The semiconductor device according to claim 2, wherein said I/O circuit is arranged at the edge side of said semiconductor chip, in which said semiconductor device is formed, relative to said pad.

5. The semiconductor device according to claim 1, wherein the first region of said pad is arranged above said I/O circuit.

6. The semiconductor device according to claim 5, wherein the number of wiring layers of the first region of said pad is fewer than the number of wiring layers of the second region of said pad.

7. The semiconductor device according to claim 6, wherein the first region of said pad is formed in one layer, and the second region of said pad is formed in the layer in which the first region is formed, and in one layer immediately below of it.

8. The semiconductor device according to claim 5, wherein the first region of said pad is a region for carrying out bonding, and the second region is a region for carrying out inspection.

9. The semiconductor device according to claim 5, wherein at least one layer among the layers in which the second region of said pad and said I/O circuit are respectively formed, is identical.

10. The semiconductor device according to claim 1, wherein an opening region of a cover layer of said pad is in common for the first and second regions.

11. The semiconductor device according to claim 1, wherein an opening region of a cover layer of said pad is formed on the first and second regions, respectively.

12. The semiconductor device according to claim 1, wherein the whole of said pad is arranged above said I/O circuit.
